(19) United States
(12) Patent Application Publication
(10) Pub. No.: US 2005/0068125 A1
(43) Pub. Date: Mar. 31, 2005

(54) Symmetrically-operating reactance filter

(76) Inventors: Michael Unterberger, Unterhaching (DE); Pasi Tikka, Munich (DE)

Correspondence Address: FISH & RICHARDSON PC, 225 FRANKLIN ST, BOSTON, MA, 02110, US

(21) Appl. No.: 10/499,183

(22) PCT Filed: Dec. 5, 2002
(86) PCT No.: PCT/DE02/04464

(30) Foreign Application Priority Data
Dec. 21, 2001 (DE) 101 63 462.5

(51) Int. Cl. H03H 9/54

(52) U.S. Cl. 333/190

(57) ABSTRACT

For a symmetrically working reactance filter with steep flanks, a low pass-band ripple, and good near and remote selection, it is recommended that partial circuit structures (A, B) of symmetrically working ladder-type filters and symmetrically working lattice-type filters are combined into a new filter. In this, reactance elements are used that are realized by the most varied techniques, such as, for example, the SAW technique or as BAW resonators.

Reactance filters, also called branching filters, are realized as networks of reactance or impedance elements. For this, reactance elements are generally arranged in branching circuits, in which at least one serial branch of the circuit is connected by wire to at least one parallel branch. The reactance elements are arranged in both the serial and the parallel branches.

To form such a filter with symmetric input and output, two possibilities exist in principle. In a symmetric ladder type filter, the reactance elements are arranged in two serial branches that are bridged by wire to parallel branches. In a symmetric lattice filter, the reactance elements are arranged in two serial branches that are bridged crosswise to parallel branches. Each of these basic filter types has specific filter characteristics. The ladder-type filter has, as a special advantage, steep flanks in the transition region and deep-reaching pole points (notches), while a lattice-type filter has, as special advantages, a lower insertion loss and a lower pass-band ripple connected with extremely high stop-band suppression.

Reactance filters can be realized by various techniques, independent of the two basic types. For example, it is possible to form the reactance elements as electric swing circuits (L and C members), as crystal resonators, as surface-wave resonators, or as BAW (Bulk Acoustic Wave) resonators (also called FBARs ({Thin Film Bulk Acoustic Resonators} or TFR {Thin Film Resonator}). In this, only the reactance elements are realized differently, while the manner of switching can be the same for all filter techniques. Symmetric ladder-type filters with BAW resonators as impedance elements are known, for example from U.S. Pat. No. 5,910,756. Symmetric lattice filters with BAW resonators are known, for example, from an article by K. M. Lakin et al: “Development of Miniature Filters for Wireless Application,” Microwave Symposium Digest, EEE MTT-S International 1995, pages 883-886.

Mobile communication systems often need filters that have good near selection at a distance of about 20 to 100 MHz from the edges of the pass band in order to suppress each reference band of the system. For an RX filter (receiving filter), for example, high near selection in the region of the TX band is required, while a TX filter (transmitting filter) requires high suppression of the corresponding receiving band (RX band). For the EGSM mobile-radio system, the TX band is, for example, at a distance of only 10 MHz from the pass band. In addition, this system requires a high remote selection at a distance of 100 to 4000 MHz from the pass band in order to suppress disturbing wave components from other mobile communication systems, harmonic oscillations, and interferences. To meet these requirements, a filter is necessary that has steep flanks, high stop-band suppression over a broad frequency range, and a low insertion loss. At this time, however, none of the known symmetric reactance filters meet all of the requirements mentioned.

The task of the present invention is therefore to provide a reactance filter that has a low insertion loss, a pass band with steep flanks and low ripple, high stop-band suppression, and good remote selection.

This task is solved according to the invention by a reactance filter with the characteristics of claim 1.

Advantageous forms of the invention emerge from additional claims.

With the invention, a reactance filter is provided for the first time that combines the advantages of the ladder-type and the lattice-type filters. A filter according to the invention has components from ladder-type filters as well as components of lattice-type filters that are combined into one filter. Between the two, circuit branches are arranged that serve as input and output gates, each with two connectors that can be operated symmetrically. In both circuit branches, there exist branching points connected between the two circuit branches that connect the two circuit groups. In each connecting branch, a second reactance element is arranged. In both circuit branches, first reactance elements are arranged that are connected in series and arranged symmetrically to each other.

First connecting branches are provided that connect branching sites to each other in a symmetric arrangement. In addition, second connecting branching sites are also provided, each of which connects two sequential branching sites in the first circuit branch in pairs with each of two sequential branching sites in the second circuit branch. Although the sequential branching sites in the first and second circuit branches are arranged symmetrically, the connecting branches are connected through a cross. Between the sequential branching sites in this case, a first reactance element is arranged in the two circuit branches.

Since, as stated, the functionality and the characteristics of a reactance filter are independent of the type of reactance elements, they can be realized by various techniques. For example, it is possible to realize the reactance elements as resonators that work with acoustic waves, for example as surface-wave components (SAW resonators), as BAW resonators, as FBAR resonators, or as stacked-crystal resonators (bundled resonators). For the resonators, it is always true that the resonance frequency of the first reactance elements in the two circuit branches is higher than that of the second reactance elements arranged in the connecting branches. Advantageously, the resonance frequencies of the reactance elements are set in such a way that the resonance frequency of the first reactance elements is approximately equal to that of the anti-resonance frequency of the second reactance elements. This can be set for SAW resonators through suitably different finger periods and for BAW resonators by a suitable variation of the layer thicknesses of the material layers forming the resonator. Since the difference between the resonance frequencies between first and second reactance elements (resonators) is low in the filters according to the invention, different resonance frequencies can be set in BAW resonators simply by trimming the layer thicknesses. The trimming in this case involves removing material from layer regions or later depositing of additional material to layer regions. It is also possible to achieve different resonance frequencies with constant layer thickness, if necessary, to the extent that the materials have different acoustic characteristics.

A BAW resonator consists, according to a simple embodiment, of a thin film of a piezoelectric material that is provided on both the top and bottom sides with an electrode. Ideally, this structure is surrounded by air on both electrode sides. When an electric voltage is applied to the electrodes, an electric field affects the piezoelectric material, in consequence of which the piezoelectric material converts part of the electrical energy into mechanical energy in the form of acoustic waves. These spread out parallel to the direction of the field as so-called volume waves and are reflected at the edge surfaces between the electrode and the air. At a particular frequency, fr, depending on the thickness of the piezoelectric layer or on the thickness of the volume oscillator, the resonator shows a resonance and therefore behaves like an electric resonator.

Another embodiment of a BAW resonator that can also be used in the reactance filters according to the invention advantageously has a multilayer structure. In this case, an acoustic mirror, a first electrode layer, a piezoelectric layer, and finally a second electrode layer are arranged on one top of another over the entire area. The acoustic mirror in this also has alternating layers of lower and higher acoustic impedance, whereby the layers have, depending on the spreading rate of the acoustic waves in said layer material, a thickness of λ/4. At most two to ten pairs of λ/4 layers of different impedances are required for adequate reflection of acoustic waves.

Materials for layers with lower acoustic impedance are especially SiO₂, while tungsten is advantageously chosen as a material for layers with higher acoustic impedance. In principle, however, it is also possible to use other combinations of materials with especially high differences in acoustic impedance for the acoustic mirror in BAW resonators in filters according to the invention.

Advantageously, a reactance filter according to the invention, constructed from BAW or FBAR resonators, is realized on a single common substrate. For this, all layers are generated on top of one another by corresponding, suitable, thin-layer processes and are structured individually as needed for the formation of the individual resonators and the metal platings that combine them. For this, the substrate must have only a mechanical carrier function and serve as the base for depositing the material layers that form the filter. Advantageously, the substrate is adapted to the thermal-expansion coefficients of the layer materials arranged above it. Even more advantageous is a substrate of a semiconductor material into which circuits for operating the reactance filter can be integrated. It is also possible to use a multilayer substrate, whereby the switching of individual filter elements (reactance elements) can take place inside the substrate, thus between two partial layers of a multilayer substrate. Such partial layers can also include organic or ceramic layers in this case. The substrate can also be an LTCC ceramic into which, if necessary, required passive components of the filter according to the invention can be integrated. Such passive components can form an adjustment network for the filter, which can serve, for example, as an impedance, capacitance, or phase adjustment.

As electrode layers for BAW resonators, aluminum, molybdenum, tungsten, or gold are suitable, which can be deposited in a simple manner in a thin-layer process. Preferred materials for the piezoelectric layer that can also be applied in a thin-layer process are, for example, aluminum nitride or zinc oxide.

The thickness of the resonator body determines the resonance frequency of the resonator. According to oscillation mode set, which can be influenced within certain limits by appropriate steps, the resonator body also has a layer thickness that is a multiple of λ/2. Advantageously, λ/2 is chosen for the total thickness of a resonator without an acoustic mirror.

In the following, the invention will be explained in more detail by means of embodiment examples and the associated drawings.

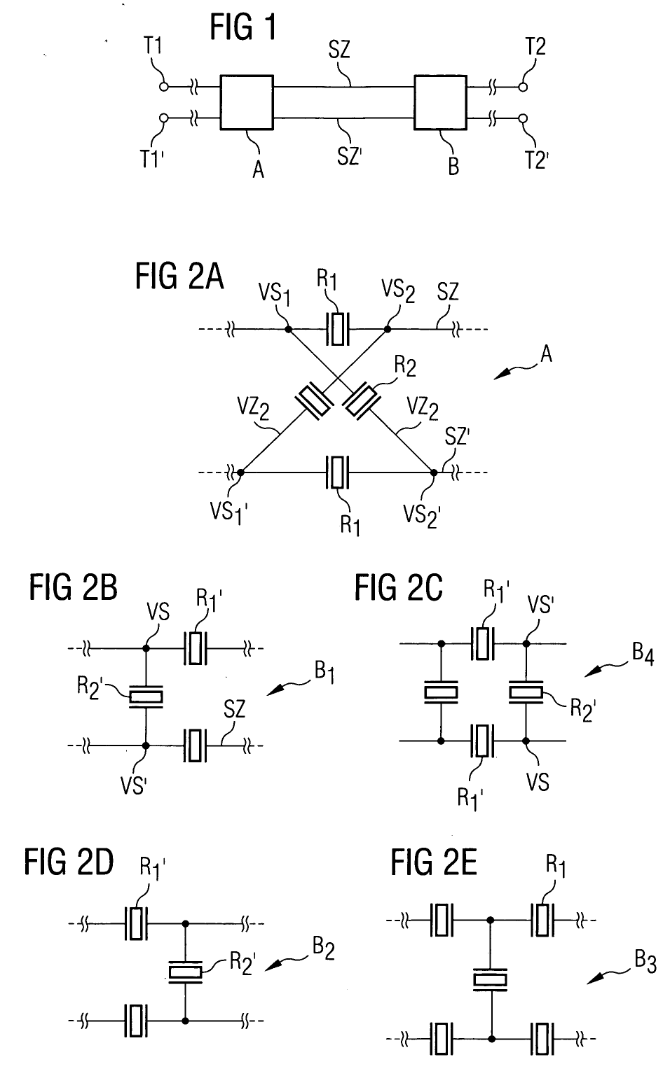

FIG. 1 shows a reactance filter according to the invention in a schematic view.

FIG. 2 shows various substructures of a reactance filter according to the invention.

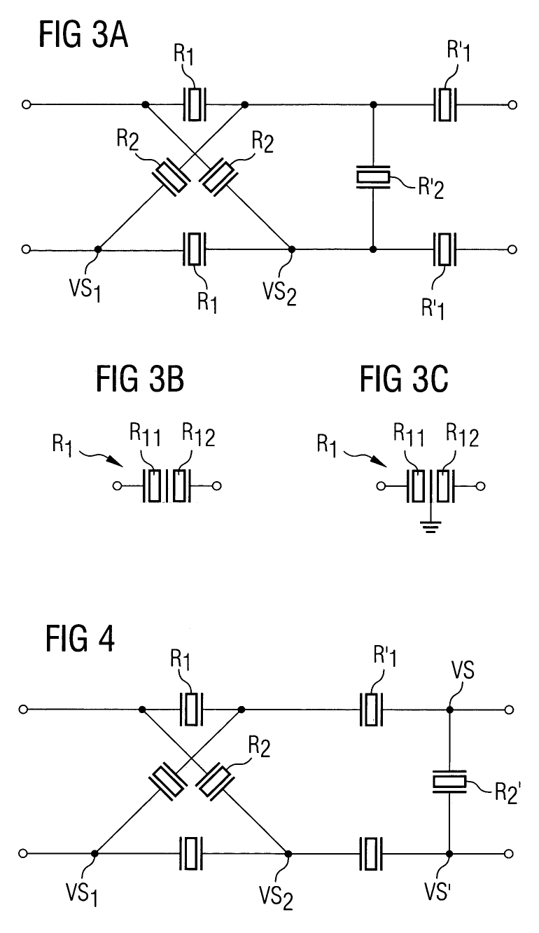

FIG. 3 shows a circuit arrangement of a reactance filter according to the invention.

FIGS. 3a and 3b show a resonator that can be used in a reactance filter according to the invention, with two acoustically coupled partial resonators, in a schematic view.

FIGS. 4 through 6 show various circuit arrangements of reactance filters according to the invention.

FIG. 7 shows the passage curve of a reactance filter according to the invention.

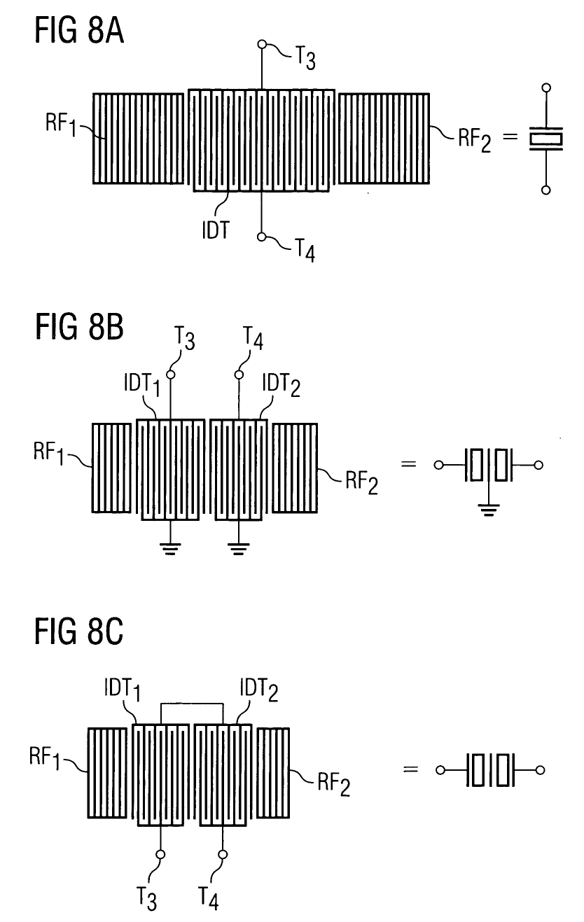

FIG. 8 shows a DMS filter that can be used in reactance filters according to the invention.

FIG. 8a shows a DMS filter that can be used in reactance filters according to the invention.

FIG. 8b shows another reactance element that can be used in reactance filters according to the invention.

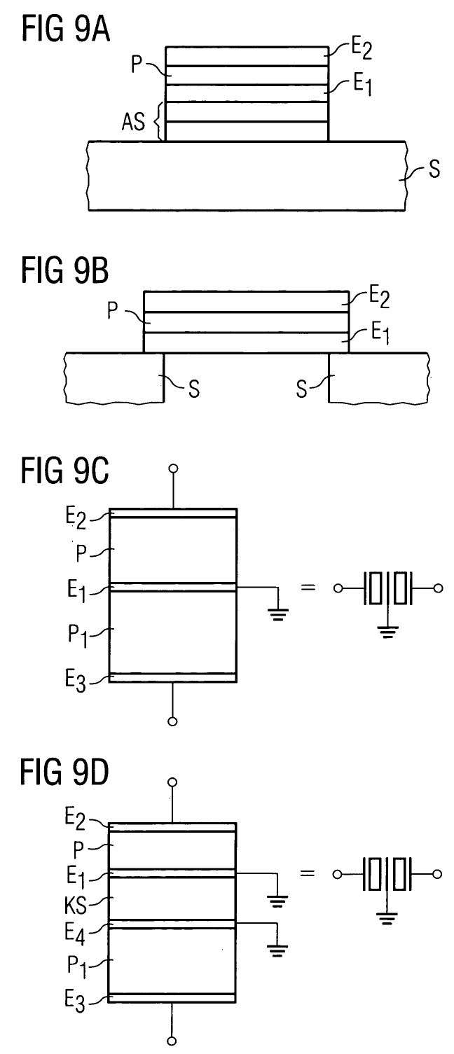

FIG. 9 shows a known BAW resonator that can be used in reactance filters according to the invention.

FIG. 9c shows a known stacked-crystal resonator that can be used in reactance filters according to the invention.

FIG. 9d shows another known stacked-crystal resonator that can be used in reactance filters according to the invention.

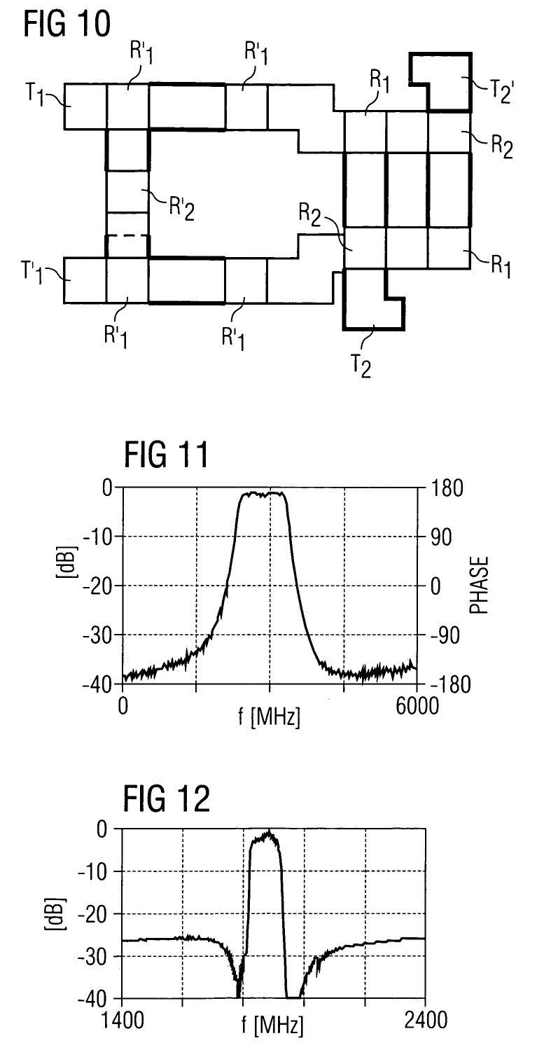

FIG. 10 shows a reactance filter realized on a common substrate by the BAW-resonator technique, in a schematic top view.

FIG. 11 shows the passage curve of a known lattice-type filter.

FIG. 12 shows the passage curve of a known ladder-type filter.

FIG. 1 shows the simplest embodiment of the invention in a schematic view. The reactance filter according to the invention consists of two gates that can be controlled symmetrically, used as input to and output from filter, with connectors T1, T1′, and T2, T2′. Between each pair of connectors T1/T2 and T1′/T2′, a circuit branch SZ, SZ′ is arranged that connects the input of one gate to the output of the other. A filter according to the invention now consists of at least one circuit structure A and one circuit structure B, which has two input connections for circuit branch SZ, SZ′ and two outputs for connection to the next circuit structure. Circuit structure A in this case includes a basic element of a lattice-type filter and circuit structure B at least one basic element of a ladder-type filters.

FIGS. 2A through 2E give various circuit structures for A and B that can be used in a filter according to the invention according to FIG. 1. The circuit symbol for reactance elements R1 and R2 corresponds to the resonators in this case, which, however, can be realized by various techniques. FIG. 2A shows a circuit structure, A, that corresponds to the simplest lattice-type filter. Two circuit branches, SZ, SZ′, parallel to each other, are bridged by two connecting branches VZ, VZ′. In this case, the connecting branches VZ each connect a branching site VS in each of the two circuit branches SZ, SZ′. The two connecting branches VZ connect pairs of branching sites VS together in the two circuit branches SZ in a crossing arrangement, so that a first branching site VS1 in the first circuit branch SZ is connected to a second branching site VS2′ in the second circuit branch SZ′ and a branching site VS2 in the first circuit branch SZ is connected to a branching site VS1′ in the second circuit branch SZ′. In each circuit branch SZ, first reactance elements R1 are arranged between the two branching sites VS. Between the branching sites, two reactance elements R2 are connected in the connecting branches VZ in series with the connecting branch.

FIG. 2B shows a simple circuit structure B1 of the ladder type. This consists of two circuit branches SZ, SZ′, in each of which a first reactance element R1′ is connected in series. Between two branch sites VS, VS′, a connecting branch VZ′ is connected, in which a second reactance element R2′ is arranged.

In FIG. 2C, the circuit structure B1 of FIG. 2B is expanded with another connecting branch, VZ, that connects two additional branching sites VS1, VS2 to the right of the first reactance elements in the two circuit branches SZ.

FIG. 2D shows a circuit structure B2, that acts like an image and a mirror image to the circuit structure B1 of FIG. 2B.

In FIG. 2E, a circuit structure B3 is shown in which the circuit structure B2 from FIG. 2D is expanded in each circuit branch with a first reactance element R1, R1′ in each case, which is arranged to the right of the branching site VS of connecting branch VZ in each case.

A reactance filter according to the invention can now consist of an arbitrary combination of circuit structures A and B (B1 through B4). In this case, the same circuit structures can also be arranged one after another. A condition, however, is that the known relevant design rules for ladder-type or lattice-type filters be observed. The concerns, especially, the condition of equal impedance connections, according to which the same connection impedance must be given between the connecting sites of two circuit structures. A design that follows this rule strictly will be called an image-parameter design.

In the case of type B circuit structures connected one after another, arrangements can be used in which either two first reactance elements are connected directly in series in a circuit branch, without connecting branches being present between them, or in which two connecting branches are each placed directly adjacent to a second reactance element, without first reactance elements existing between their branching sites VZ. Such structures of serial first reactance elements or parallel second reactance elements can always be combined in this case, whereby the static capacitance of an additional element resulting from the combination of two serial first resonators R1 is halved, while the static capacitance of a combination element of two parallel second resonators R2 is doubled.

FIG. 3 shows a concrete circuit structure of a reactance filter according to the invention, given only schematically in FIG. 1. This includes a first circuit structure, A, and a second circuit structure, B1, as already shown in FIGS. 2A and 2B. The combination of these two circuit structures A and B1 is connected in series between the two gates formed by the connections T1, T1′ and T2, T2′.

FIG. 3a shows in a schematic view a known resonator R1 that can be used in reactance filters according to the invention with (here, two) acoustically coupled partial resonators that can be, for example, a stacked-crystal resonator or else implemented as an interdigital converter arranged in an acoustic track (such as, for example, in a DMS filter). The resonator R1 has two acoustically coupled partial resonators R11 and R12, connected together.

FIG. 4 shows another embodiment of the invention that corresponds to connecting circuit structures A and B2.

FIG. 5 shows another embodiment, corresponding to connecting partial circuit structures A and B4 in series.

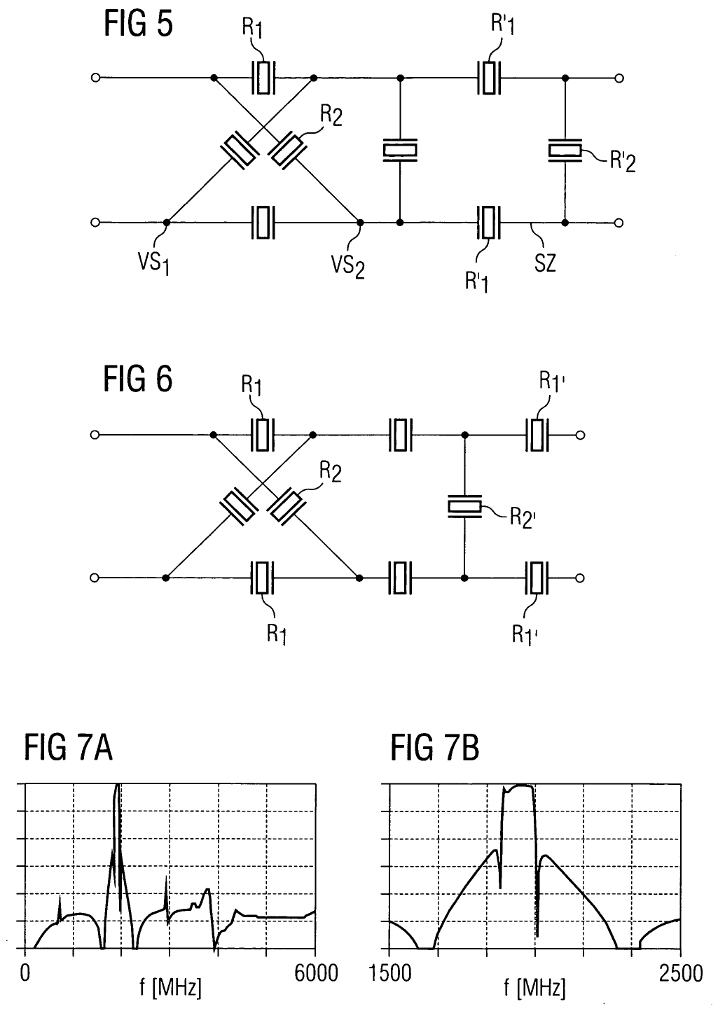

FIG. 6 shows an embodiment of the invention that corresponds to connecting partial circuit structures A and B3.

Although embodiment examples illustrated in FIGS. 3 though 6 already represent complete filters, they can be combined or connected in series with arbitrary additional partial circuit structures of type A or B.

FIG. 7 shows the passage curves of a reactance filter according to the invention obtained from a simulation calculation. It can be seen that the filter according to the invention has, on the one hand, the steep flanks and the deep-reaching pole sites (notches) that are typical of a symmetric ladder-type filter. On the other hand, the filter according to the invention also shows the very good remote selection that is typical of a lattice-type filter. FIG. 7A shows here, to clarify the remote selection, the same passage curve, while in FIG. 7B the pass band is shown enlarged so that the steep flanks of the pass band can be well recognized.

FIG. 8 shows a possible way in which a reactance element of a reactance filter according to the invention can be implemented as a one-gate resonator in the surface-wave technique. The metal-plating structure is illustrated, which has an interdigital converter IDT arranged between two reflectors RF1, RF2. The connectors of the one-gate resonator are shown on the interdigital converter, IDT, and are indicated with T3 and T4. To the right of the concrete structure, a circuit symbol that can be used for this is illustrated for a (general) resonator, as is also used in FIGS. 2 through 6.

FIG. 8a shows a possible way in which a reactance element of a reactance filter according to the invention as a DMS filter (DMS=Double Moded Surface Acoustic Wave), realized by the surface-wave technique. The metal-plating structure of the DMS filter exhibits an interdigital converter IDT1 that is acoustically coupled with an additional interdigital converter IDT2. The two interdigital converters are bounded on both sides by reflectors RF1, RF2. The connectors of the DMS filter are indicated with T3 and T4. To the right of the concrete structure a circuit symbol that can be used for this is shown for two coupled partial resonators that correspond to the resonator illustrated in FIG. 3b.

FIG. 8b shows another reactance element that can be used in a reactance filter according to the invention. The reactance element has two acoustically coupled interdigital converters, IDT1 and IDT2, in this embodiment that are connected in series between connectors T3 and t4. To the right of the concrete structures, a circuit symbol that can be used for this is illustrated for two coupled partial resonators, which symbol corresponds to the resonator illustrated in FIG. 3a.

FIG. 9 shows embodiments of known BAW or FBAR resonators. In Figure A, such a resonator is arranged, consisting of a first electrode layer E1, a piezoelectric layer P, and a second electrode layer E1 through an acoustic mirror AS that in turn is attached to a substrate S. The acoustic mirror AS in this case can have various numbers of A/4 layers of alternating higher and lower impedance. The materials already given are suitable for the substrate, as well as for the functional layers E and P of the resonator.

FIG. 9B shows another variant of a thin-layer resonator that, here, rests freely load-bearing on two support points of a substrate. The free space below the resonator, which is also called an air gap or air slit, serves to keep the acoustic energy within the resonator. The impedance difference at the phase boundary between electrode layer or membrane layer and air is so high that a complete reflection of the acoustic wave occurs at the boundary layer with air. The air slit here assumes the role of the acoustic mirror.

An example structure of a known stacked-crystal resonator is shown in FIGS. 9c and 9d. A first partial resonator is formed in both diagrams by a first electrode E1, a piezoelectric layer P, and a second electrode E2. A second partial resonator is formed in FIG. 9c by the first electrode E1, a piezoelectric layer P1, and a third electrode E3. In the embodiment example shown in shown in FIG. 9d, the second partial resonator is formed from a fourth electrode E4, the piezoelectric layer P1, and the third electrode E3. The partial resonators stacked on top of one another are coupled acoustically by means of a common electrode (E1 in FIG. 9c) or by means of a coupling layer KS between the electrodes E1 and E4 facing each other (see FIG. 9d). The electrodes E1, E4 can be connected to ground, as is made clear in FIGS. 9c, 9d. This connection is schematically shown in FIG. 3b.

FIG. 10 shows a possible way in which the reactance filter according to the invention can be constructed of BAW resonators and how these resonators could be integrated onto a common substrate. Each resonator can, for example, be formed here according to FIG. 9A. The connection is made by the integrated structure, in which conducting paths can be formed between individual electrode layers E1, E2 of reactance elements that are adjacent or are to be connected together, by intermediate structuring steps. The connection is made by metal plating that connects the individual electrode layers of resonators that are adjacent or are to be connected together by means of metal-plated paths. The metal-plated paths MB illustrated with thicker lines are connected together in this case in the electrode layers beneath the plane of the diagram, while the metal-plated paths MB illustrated with normal or thinner hatching shows those in the electrode layers E2 above the plane of the diagram. The resonators are illustrated here as rectangles, corresponding to the preferred area of BAW resonators.

The real structure illustrated in FIG. 10 for a reactance filter according to the invention corresponds to general circuit structure illustrated in FIG. 6. Only partial circuit structure A has been replaced by partial circuit structure B3. Connectors T1, T1′, and T2, T2′ correspond here to the metal-plated areas applied to the surface of the substrate or another surface layer of the substrate, to which external circuits can be soldered or connected in another manner.

FIG. 11 shows the passage curve of a known lattice-type filter, here circuit structure A of FIG. 2A. The low insertion loss and the good near selection can be recognized well, as can the flanks of the pass band, which are not all that steep.

FIG. 12, in contrast, shows the passage curve of a known ladder-type filter, for example the circuit structure B4 (see FIG. 2C), realized in the SAW technique. Here, the steep flanks and the deep pole sites can be well recognized, as can the disadvantageous pass-band ripple and comparably worse remote selection in the stop band.

In comparing the passage curves of the know ladder-type and lattice-type filters with those of the passage curves shown in FIG. 7 for the filter according to the invention, it can be seen that the invention exclusively combines the advantageous characteristics of the two known filter types in a surprising way, without having to accept their disadvantages at the same time. With the filters according to the invention, therefore, the requirements of mobile-radio systems with closely adjacent reference bands for RX and TX filters can be met for the first time, for example those of the above-mentioned EGSM standard, for example.

Although it has been possible to explain the invention here only by means of a few embodiment examples, other variations in the structure of the reactance filter according to the invention can be imagined. In addition to resonators working with acoustic waves, the invention can also be implemented with other reactance elements, for example with LC members or with crystal resonators. Also, the materials given for BAW resonators are not limiting for the invention since the reactance elements or resonators can also be realized in other ways.

1. A reactance filter comprising:
a first gate comprised of, first and second connectors connected to first and second circuits, respectively;
a second gate comprised of third and fourth connectors connected to the first and second circuits, respectively:
a first circuit structure connected to the first gate via the first and second circuits; and
a second circuit structure connected to the second gate and to the first circuit structure via the first and second circuits:
wherein at least one of the first and second circuit structures comprises:
series reactance elements connected on the first and second circuits; and
parallel reactance elements cross-connected between the first and second circuits, the parallel reactance elements contacting the first and second circuits at contact points, at least one of the series reactance elements being connected between two contact points on each of the first and second circuits.

2. The reactance filter of claim 1, wherein the series and parallel reactance elements comprise resonators that produce acoustic waves.

3. The reactance filter of claim 2, wherein a resonance frequency of the series reactance elements is higher than a resonance frequency of the parallel reactance elements.

4. The reactance filter of claim 2, wherein a resonance frequency of the series reactance elements is approximately equal to an anti-resonance frequency of the parallel reactance elements.

5. The reactance filter of claim 1, wherein the series reactance elements and the parallel reactance elements are comprise Bulk Acoustic Wave (BAW) resonators.

6. The reactance filter according to claim 5, wherein the BAW resonators each have a multilayer structure comprising an acoustic mirror, a first electrode a piezoelectric layer, and a second electrode arranged as a stack on substrate.

7. The reactance filter of claim 1, wherein one of the first and second circuit structures comprises additional series reactance elements on the first and second circuits and at least one additional parallel reactance element connecting the first and second circuits.

8. The reactance filter of claim 7, wherein the at least one additional parallel reactance element comprises two additional parallel reactance elements with the additional series reactance elements located between the additional parallel reactance elements.

9. The reactance filter of claim 7, wherein the at least one additional parallel reactance element comprises a single additional parallel reactance element, and the additional series reactance elements comprise one additional series reactance element located on each side of contact points of the additional parallel reactance element to the first and second circuits.

10. The reactance filter of claim 7, wherein the at least one additional parallel reactance element comprises a single additional parallel reactance element, and the additional series reactance elements comprise one additional series reactance element located on one side of contact points of the additional parallel reactance element to the first and second circuits.

11. The reactance filter of claim 10, wherein the one side comprises a side of the single additional parallel reactance element near to a circuit structure.

12. The reactance filter of claim 10, wherein the one side comprises a side of the single additional parallel reactance element away from a circuit structure.

13. The reactance filter of claim 1, further comprising additional parallel reactance elements cross-connected between the first and second circuits.

14. The reactance filter of claim 1, wherein the series and parallel reactance elements comprise Bulk Acoustic Wave (BAW) resonators on a common substrate.

15. The reactance filter of claim 14, wherein the BAW resonators comprise a common acoustic mirror for all reactance elements, and wherein resonance frequencies of series and parallel reactance elements are set by trimming a layer of at least one of the series and parallel reactance elements.

16. The reactance filter of claim 1, wherein the series and parallel reactance elements comprise stacked-crystal resonators or partial resonators of a resonator or DMS filter working with acoustic surfaces coupled together acoustically.
